(19) United States
(12) Patent Application Publication
(10) Pub. No.: US 2010/0108134 A1
(43) Pub. Date: May 6, 2010

(54) Thin two sided single crystal solar cell and manufacturing process thereof

(75) Inventor: Kramadhati V. Ravi, Atherton, CA (US)

Correspondence Address: PILLSBURY WINTHROP SHAW PITTMAN LLP, P.O. BOX 10500, MCLEAN, VA, 22102, US

(73) Assignee: Crystal Solar, Inc., Santa Clara, CA (US)

(21) Appl. No.: 12/290,588

(22) Filed: Oct. 31, 2008

(51) Int. Cl. H01L 31/00; H01L 21/306; H01L 31/18

(52) U.S. Cl. 136/256; 438/694; 438/72; 257/E21.219; 438/96; 438/98; 257/E31.127; 257/E31.11

(57) ABSTRACT

A design and manufacturing method for a photovoltaic (PV) solar cell less than 100 μm thick are disclosed. A porous silicon layer is formed on a wafer substrate. Portions of the PV cell are then formed using diffusion, epitaxy and autodoping from the substrate. All front side processing of the solar cell (junctions, passivation layer, anti-reflective coating, contacts to the N⁺-type layer) is performed while the thin epitaxial layer is attached to the porous layer and substrate. The wafer is then clamped and exfoliated. The back side of the PV cell is completed from the region of the wafer near the exfoliation fracture layer, with subsequent removal of the porous layer, passivation, patterning of contacts, deposition of a conductive coating, and contacts to the P⁺-type layer. During manufacturing, the cell is always supported by either the bulk wafer or a wafer chuck, with no processing of bare thin PV cell

### CROSS-REFERENCE TO RELATED APPLICATIONS

This application claims the benefit of U.S. Provisional Application Ser. No. 61/068,629, filed Mar. 8, 2008, which is expressly incorporated by reference herein.

### BACKGROUND OF THE INVENTION

1. Field of the Invention

This invention relates generally to the field of solar cell manufacturing, and more particularly to methods of manufacturing solar cells formed using thin epitaxial films grown on single crystal silicon wafer substrates.

2. Description of the Related Art

The majority of single crystal silicon photovoltaic (PV) solar cells fabricated today employ contacts on both the front and back surfaces, with doping of the diode structure in the PV cell done using conventional furnace diffusion of boron (P-type) or phosphorous (N-type) dopants. Typically, prior art fabrication processes for photovoltaic (PV) solar cells use thick wafers (typical thickness of about 180 μm) for the substrate. A sequence of furnace diffusion steps are then used to dope the various P-type and N-type regions in the PV cell, forming a diode structure in which electron-hole pairs are created by the photoelectric effect within the doped (either P or N-type) bulk material of the PV cell. FIGS. 14 through 18 illustrate some steps of a prior art PV cell design and fabrication process for a thin PV solar cell with front side and back side contacts.

FIG. 14 shows a schematic side cross-sectional view of a blank wafer 3000 before a prior art process for fabrication a PV solar cell. The wafer 3000 can be either P-type or N-type.

As shown in a schematic side cross-sectional view in FIG. 15, furnace diffusion phosphorous dopant is diffused in a furnace into the front side (upper surface in FIG. 15) of the wafer 3000 of FIG. 14 to form an N⁺-type layer 3002. Due to the high temperature of the furnace doping process, an oxide layer 3004 forms on the upper surface of the N⁺-type layer 3002. Typically the phosphorus diffusion process is conducted by the use of either phosphorus oxychloride (POCl₃) or phosphoric acid and a carrier gas which contains oxygen. Consequently, the oxide layer 3004 forms on the upper surface of the N⁺-type layer 3002. The oxide layer 3004 must be removed prior to subsequent processing.

As shown in a schematic side cross-sectional view in FIG. 16, the oxide layer 3004 of FIG. 15 formed during the furnace diffusion is removed. As shown in a schematic side cross-sectional view of FIG. 17, screen printing and firing an aluminum layer 3004 on the wafer of FIG. 16 forms a P⁺-type layer 3012 in the silicon wafer 3000 adjacent the aluminum layer 3014. The aluminum layer 3004 acts as a conducting layer. Alternative conductive layers may be a sandwich of titanium nitride or tantalum with copper. In the current state of the art, the back P⁺-P junction is formed by screen printing a paste of aluminum on the back of the solar cell and firing (alloying) it into the silicon. The aluminum dissolves in the silicon to form a P⁼ region. The resulting structure in FIG. 17 includes the N⁼-layer 3002 and the P⁺-layer 3012 sandwiching the silicon wafer 3000. Note that although the diffusion is shown coming in the bottom of the wafer in FIG. 17, the actual orientation of the wafer during the prior art processing steps in FIG. 17 may be inverted compared with the orientations shown in FIGS. 14-16.

Following the formation of an N⁺-P junction at the top and a P⁺-P junction at the bottom, a layer of silicon nitride is deposited on the front side the device to function as an anti-reflection coating. Then, silver is screen printed on both side, in the form of a grid at the top and in the form of a pad at the bottom. The silver is fired to make contacts to the solar cell.

A disadvantage of this prior art PV cell fabrication process is the need for thick wafers and the resulting use of substantial amounts of silicon in the completed PV cell, raising materials costs. It would be desirable to fabricate PV cells with reduced thickness in order to decrease the usage of silicon, thereby reducing materials costs in the completed PV cell.

Another disadvantage of the use of furnace diffusion in the formation of the N⁺-type layer 2002 and the P⁺-type layer 2012 is the lack of control over the dopant profiles (typically boron or aluminum for P⁺ and phosphorus for N⁺) as a function of depth into the wafer 3000 within the N⁺ layer 2002 and the P⁺ layer 2012. This lack of control is inherent in the furnace diffusion process, which relies on the thermal diffusion of dopants through the silicon lattice. The furnace diffusion doping process limits the sharpness of the two junctions (an N⁺-P junction between the wafer 3000 and the N⁺-type layer 3002, and a P⁺-P junction between the wafer 3000 and the P⁺-type layer 3012) in the PV solar cell. Abrupt or sharp junctions aid in the achievement of higher voltages in the solar cell. The lack of sharpness of the junctions increases the undesirable process of electron-hole recombination within the PV solar cell. In addition, typically precipitates of the dopant species form in a solid solution within the bulk silicon material of the wafer 3000 at the surface through which diffusion is occurring. The precipitates cause excessive electron-hole recombination. Thus, it would be desirable to employ a process for forming P⁺ and N⁺-type regions which permits better control of dopant spatial distributions (profiles) as well as avoiding the formation of precipitates of the dopant species at the wafer surface during doping.

Since materials costs are an important contributor to the overall costs of PV cells, reducing materials costs is clearly an important goal. Since silicon represents the major cost in the manufacture of PV products, it is desired to develop processes for manufacturing PV silicon wafers that are much thinner than the typical thicknesses of about 180 microns used to fabricate conventional single crystal solar cells integrated circuits. One method has been proposed for manufacturing very thin solar cells includes exfoliating a surface layer from a silicon mother wafer by creating a damaged layer within the bulk wafer material by implanting high energy (multiple MeV) hydrogen iona to damage the silicon structure at a known depth as determined by the ion energy. Following hydrogen implantation, the thin wafer may be peeled off the bulk wafer by exfoliation at the damaged layer. This method is expensive due to the need for high voltage implantation over a large area. In addition, a number of processing steps must be performed on the thin wafer after exfoliation for the fabrication of solar cells. Such thin wafer processing can be extremely difficult with high breakage and damage rates and costly handling methods.

### SUMMARY OF THE INVENTION

The present invention provides an improved design for thin (photovoltaic (PV) solar cell which may have a thickness of less than 100 microns and preferably less than 75 microns or even 50 microns and is partially fabricated on a thick silicon wafer, for example having a thickness of at least 180 microns. The invention also includes a fabrication process for manufacturing the improved thin PV cell design.

According to one aspect of the present invention, fabrication starts with a conventional thick monocrystalline silicon wafer on one surface of which a porous layer has been created, typically by an electrochemical etching process. After creation of the porous layer, which typically has a thickness of 2 to 5 microns, the wafer may be heated to induce sufficient thermal reorganization of the silicon on the upper surface of the porous layer to enable high quality epitaxial growth of subsequent films to occur.

The growth of films using epitaxial deposition affords high materials quality as compared with the conventional method of manufacturing silicon wafers. In addition, with the formation of P-N junctions during epitaxial deposition, the possibility exists for much better control of dopant profiles including sharp junction interfaces compared with dopant profiles generated using conventional furnace diffusion. This control arises because the epitaxial growth process allows the control of dopant concentrations in the material as it is deposited and this control is accomplished by the regulation and variation of the various feed gases during the epitaxial deposition process. Dopant profiles created in the bulk material by means of furnace diffusion, in contrast, are limited by the characteristics of thermal diffusion. In addition, at the surface, the formation of precipitates of the dopant species (e.g. phosphorus) may also occur, creating an undesirable layer which can cause loss of light-generated electrons near the surface of the solar cell. Thus, the use of epitaxial deposition for the growth of the necessary P- and N-type regions in the PV cell structure of the present invention affords many advantages over prior art PV cells structures fabricated using furnace diffusion.

One aspect of the present invention employs epitaxial deposition to grow the necessary P-type and N-type layers on top of a porous layer while the porous layer and layers epitaxially deposited on it are supported on the relatively thick mother wafer so that most of the processing is performed on a thick wafer. Thereby, a sharp P-N junction may be formed during the epitaxy and not depend upon thermal diffusion. Further, the growth of the epitaxial P and N layers combines production of new material and the beginning of defining the solar cell in contrast.

During the exfoliation, the thin PV wafer of the crystalline layers to be separated may be mechanically clamped to a rigid chuck and remained clamped to this or to similar clamps during subsequent processing.

Because the doping for the P⁺-type back side layer may be autodoping, which is accomplished simultaneously with the epitaxial growth of the P-type and N⁺-type layers (which will eventually be the front of the PV cell), all processing steps required in the prior art fabrication process to create the P⁺-type back side layer may be eliminated, reducing the costs of PV cell manufacture.

The PV cell manufacturing method forming one aspect of the present invention employs epitaxial deposition to grow the P-type and N⁺-type layers of the PV cell while the cell is still attached to the bulk wafer. After growth of these layers, a significant number of cell processing operations are carried out while the thin silicon layer is still attached to the thick silicon mother substrate with a porous layer in between. The autodoped P⁺ layer may have a wider and more graded junction the P layer than junctions subsequently developed by epitaxial growth of layers of controlled doping.

The epitaxial growth enables closely controlled doping allowing the definition of sharp interfaces and junctions, particularly the P-N junction.

The N⁺-type may be textured, preferably on only one side with a planar side preferably forming one side of the P-N junction. Passivation and anti-reflection coatings can be conformally deposited on the textured side.

In the middle of cell fabrication, the processed side of the wafer is clamped on its front side to a wafer chuck and the processed layers are exfoliated from the mother wafer. All subsequent processing steps are performed on the side of the wafer which had been in proximity to the porous layer at which this exfoliation occurs—this side will be the back side of the completed PV cell. Thus, no processing of the PV cell, either front-side or back-side, is performed without some means of solid mechanical support for the thin PV cell. During the exfoliation, the thin PV wafer of the crystalline layers to be separated is mechanically clamped to a rigid chuck. Also during the processing steps subsequent to exfoliation, the PV wafer may be similarly clamped. As a result, during all steps of processing the thin PV wafer, it is connected either to a relatively thick, properly supported wafer of to a rigid chuck, thereby reducing breakage and simplifying handling. unlike the hydrogen-implantation technique of creating an exfoliation layer which lacks the ability to in situ create P-N junctions because of the sub-surface damage.

The subsequent steps may include definition of contacts on one side of the wafer while the contacts on the other side were developed while the cell was still attached to the mother wafer. The N and P layers may be interchanged.

### BRIEF DESCRIPTION OF THE DRAWINGS

FIG. 1 is a schematic side cross-sectional view of a silicon wafer with four layers grown on the top surface: a thin porous layer, a P⁺-type layer, a P-type layer, and an N⁺-type layer.

FIGS. 2A-2C show schematic side cross-sectional views of three steps in a prior art process sequence for texturing the front surface of a silicon solar cell.

FIGS. 3A-3C show schematic side cross-sectional views of three steps in a process sequence of the present invention for texturing the front surface of a silicon solar cell.

FIG. 4 is a schematic side cross-sectional view of the wafer from FIG. 1 after texturing of the front surface.

FIG. 5 is a schematic side cross-sectional view of the wafer from FIG. 4 after deposition of a passivation layer, an anti-reflective coating, and a silver contact grid on the front surface of the wafer.

FIG. 6 is a schematic side cross-sectional view of the wafer from FIG. 5 after firing (sintering) of the silver contact grid to make ohmic contact to the N⁺ layer on top of the wafer.

FIG. 7 is a schematic side cross-sectional view of the wafer from FIG. 6 after clamping to a wafer chuck.

FIG. 8 is a schematic side cross-sectional view of the wafer from FIG. 7 during exfoliation.

FIG. 9 is a schematic side cross-sectional view of the wafer from FIG. 8 after exfoliation.

FIG. 10 is a schematic side cross-sectional view of the wafer from FIG. 9 after removal of the remaining portion of the porous layer and deposition or growth of a passivation layer.

FIG. 11 is a schematic side cross-sectional view of the wafer from FIG. 10 after deposition of a patterned resist layer, followed by an isotropic etch through the passivation layer.

FIG. 12 is a schematic side cross-sectional view of the wafer from FIG. 11 after removal of the patterned resist layer, deposition of an aluminum layer, deposition of silver bus bars, and a subsequent annealing step.

FIG. 13 is a schematic side cross-sectional view of a completed thin solar cell of the present invention.

FIG. 14 is a schematic side cross-sectional view of a blank wafer at the beginning of a prior art PV cell fabrication process.

FIG. 15 is a schematic side cross-sectional view the wafer from FIG. 14 after furnace diffusion of phosphorous dopant into the front side of the wafer to form an N⁺-type layer in a prior art process.

FIG. 16 is a schematic side cross-sectional view of the wafer from FIG. 15 after removal of the oxide layer formed during the furnace diffusion of phosphorous into the wafer in a prior art process.

FIG. 17 is a schematic side cross-sectional view of the wafer from FIG. 16 after removal of the oxide layer formed during the furnace diffusion of boron into the wafer in a prior art process.

### DETAILED DESCRIPTION

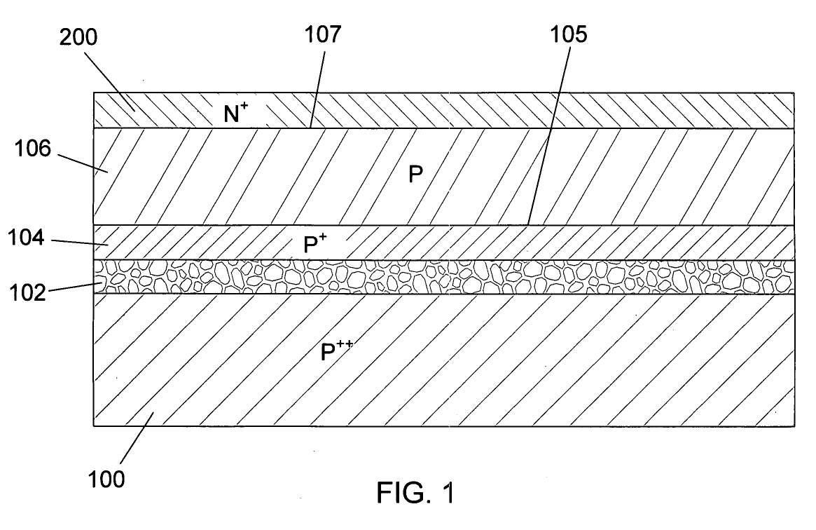

FIGS. 1 to 13 illustrate exemplary steps in the fabrication process for a thin photovoltaic cell according to one embodiment of the invention. Most figures are schematic side cross-sectional views in which the vertical dimensions are greatly enlarged relative to the horizontal dimensions. Note that this exaggeration of the vertical scale makes the profiles of the isotropic etch steps appear as vertical lines since any undercutting occurring during the isotropic etch process cannot be seen when the vertical scale is greatly enlarged.

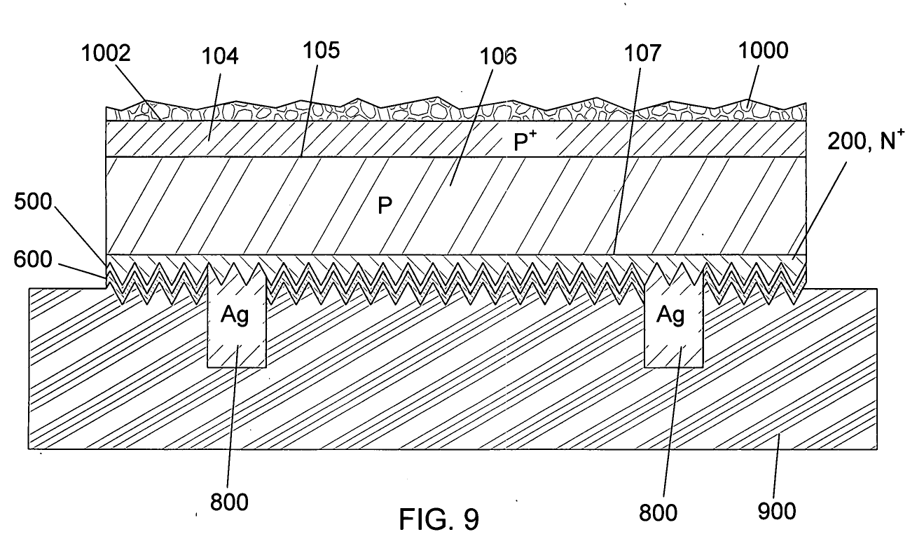

A silicon photovoltaic (PV) wafer 100 illustrated in the schematic side cross-section view of FIG. 1 is a single-crystal wafer of the type used for semiconductor integrated circuits or can be of solar grade which has typically been used in conventional single crystal silicon solar cells. Four layers are grown on its top surface: a thin porous silicon layer 102, a P⁺-type layer 104, a P-type layer 106, and an N⁺-type layer 200. In this embodiment, the silicon wafer 100 may be a heavily-doped P⁺⁺ wafer, typically with a resistivity of 0.01 to 0.005 ohm-cm. The upper surface of wafer 100 is made porous by exposing it to an anodic etching process, for example using hydrofluoric acid (HF), as illustrated in FIG. 9 of U.S. Provisional Patent Application Ser. No. 61/068,629, filed Mar. 8, 2008. The anodic etching forms pores in the surface of the wafer 100, thereby forming the porous layer 102, which has a typical thickness of about 1.0 μm. The pores are considered to be distributed at low density across the surface and to have diameters of 0.5 to 2 nm although pore dimensions depend upon processing conditions. The low density allows the majority of the surface to retain the monocrystallinity characteristic of the mother wafer 100.

After formation of the porous layer 102, the combined wafer 100 and porous layer 102 may be annealed in hydrogen to remove roughness on the upper surface of the porous layer 102. During the anneal, silicon migrates and redistributes across the upper surface and tends to partially or fully close the tops of the pores in a monocrystalline structure while the pore diameter is being reduced to probably less than 0.5 nm. This smoothing process acts to provide a smooth generally monocrystalline surface for easy subsequent growth of epitaxial silicon. The silicon layers epitaxially grown over the porous layer 102 may include defects but the crystalline orientation from one lateral side to the other follows the monocrystalline orientation of the underlying monocrystalline silicon wafer 100 and the after grown layers should be substantially monocrystalline between the locations of the pores.

The solar cell of the invention relies upon the formation of different semiconductor layers forming semiconductor junctions. The description relies upon relative doping levels, which are inverse to resistivity levels. Although the invention is not limited to these values, typically P and N layers have resistivities of 0.5 to 10 ohm-cm, P⁺ and N⁺ have resistivities of 0.05 to 0.2 ohm-cm, and P⁺⁺ and N⁺⁺ layers have resistivities of 0.005 to 0.01 ohm-cm. Thus, the doping concentrations or resistivities differ by at least a factor of 2 and preferably by at least a factor of 10. The levels of doping of the N layers need not correspond numerically to the levels of doping of the P layers.

The P⁺-type epitaxial layer 104 and the P-type epitaxial layer 106 may be derived from a single P-type silicon layer grown epitaxially on the porous layer 102 by chemical vapor deposition (CVD), with a boron dopant typically derived from boron hydride (B₂H₆) added to a silane type precursor. The doping in the wafer 100 may be a high concentration of boron (making the silicon P⁺⁺-type).

During the high temperature (typically roughly 1100° C.) epitaxial growth process of P-type silicon on top of the porous layer 102, a P⁺-type layer 104 is formed by autodoping caused by boron diffusion up from the wafer 100 and the similarly doped porous silicon layer 102 into the lower part (approximately 0.3 μm thickness) of the P-type layer being grown. Thus, the P⁺-type layer 104 is formed through this autodoping process, while the P-type layer 106 (typically 30 μm thick) is the portion of the P-type layer 106 which is not autodoped because it is beyond the diffusion range of the boron diffusing up from the wafer 100 and the porous layer 102. A P⁺-P interface 105 between the P⁺-type layer 104 and the P-type layer 106 has a wide exponentially varying dopant concentration profile characteristic of a diffusion doping.

Autodoping is well known in the art to occur during the high temperatures employed for epitaxial deposition of lightly boron doped layers on heavily doped boron layers, which causes a simultaneous diffusion of boron from the substrate part way into the light doped, epitaxial layer on top. In normal semiconductor processing this process is at best a nuisance. Any potential deleterious effects for the transistors being fabricated are avoided by ensuring that the autodoped layer is sufficiently deep to be separated from those portions of the surface of the wafer in which the device is fabricated. In the present invention, however, the inevitable autodoping arising from boron diffusion up from the bulk (heavily doped P-type) wafer, through the porous layer, and then up into the portion of the wafer destined to form the thin PV cell, is used to create the P⁺-type back side layer of the completed PV cell.

A subsequent CVD epitaxial deposition forms an N⁺-type layer 200 (typically approximately 3 μm thick) on top of the P-type layer 106 with a P-N⁺ interface 107 in between. The resistivity of the P-type layer 106 is typically 0.3 to 0.5 ohm-cm. Since the P⁺-type layer 104 is formed by diffusion up into the P-type layer 106, the P-type boron dopant distribution across the P⁺-P interface 105 between the P⁺-type layer 104 and the P-type layer 106 tends to be more graded than is typical for CVD epitaxial layers.

The epitaxial deposition process for the P-type layer 106 and the N⁺-type layer 200 allows the P-N⁺ junction 107 between the P-type layer 106 and the N⁺-type layer 200 to be more abrupt than the P⁺-P interface between the P⁺-type layer 104 and the P-type layer 106. This abrupt P-N⁺ junction 107, which is much narrower than the graded P⁺-P junction, has the benefit of enabling higher solar cell voltages, thereby improving the PV cell performance. In contrast, P-N junctions formed by diffusion are less abrupt and more graded.

The P⁺-P junction 105 is formed by the diffusion of dopants from the heavily doped wafer 100 and porous layer 102 and thus presents graded doping profile near or across the junction that is generally exponentially decreasing away from the dopant source where the exponential diffusion length is on the order of 0.1 to 0.3 microns. The exponential variation applies below the solubility limit, which is about 2*10²⁰/cm³ for phosphorus in silicon. Above the solubility limit, the excess dopant precipitates and forms a dead layer at the surface adjacent the source. On the other hand, the P-N⁺ junction 107 may be formed by two different steps of epitaxial deposition with different dopants and can be very abrupt. The doping profiles across the two epitaxially grown layers 106, 200 can be relatively flat even approaching the solubility limit in the N⁺-layer 200, but then quickly change near the junction 107 over distances substantially less than the diffusion length associated with the other junction 105.

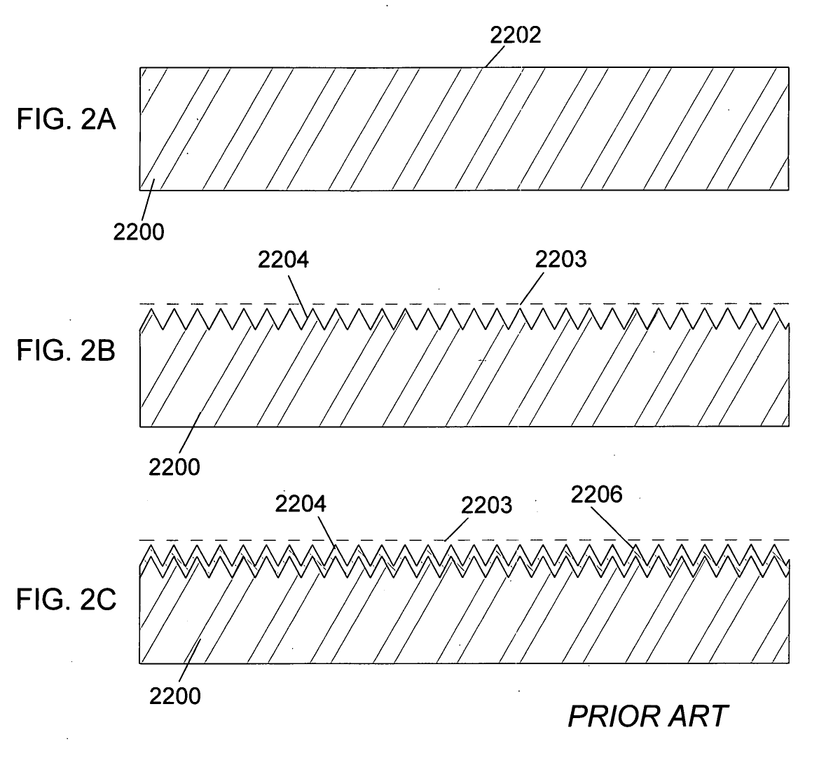

The schematic side cross-sectional views in FIGS. 2A-2C illustrate a general process sequence for texturing the front surface of a silicon PV solar cell. FIG. 2A shows a silicon PV wafer 2200 prior to the texturing and doping processes. Note that the upper surface 2202 is generally flat. As shown in FIG. 2B, the front side of the wafer is textured for form a jagged surface 2204. The original upper surface 2202 before texturing is shown here as a dashed line 2203. This texturing process may be performed a number of ways as is familiar to those skilled in the art, such as wet or dry etch. The front surface may then be furnace annealed in an N-type ambient to form a conformal N⁺-type textured layer 2206 at the surface of the front side texturing 2204. In this process, the wafer 2200 is textured before doping and the N⁺-type layer 2206 is thinner than the topography of the texturing 2204. This process advantageously reduces electron-hole recombination due to the thinner N⁺-type layer 2206. A disadvantage of this process is that the lateral resistance of the N⁺-type layer 2206 is higher due to the small vertical dimension of the N⁺-type layer 2206.

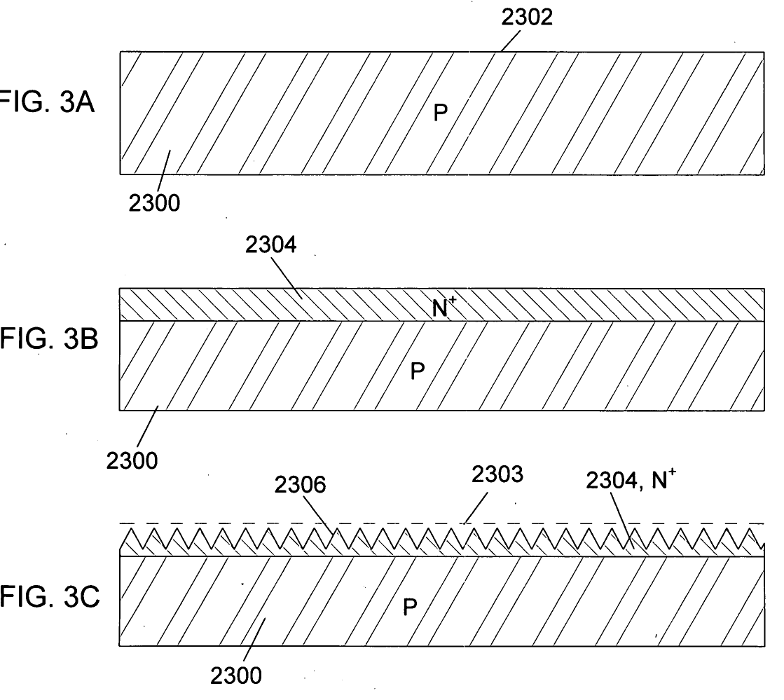

The schematic side cross-sectional views in FIGS. 3A-3C illustrate a process sequence of the present invention for texturing the front surface of a silicon PV solar cell. As shown in FIG. 3A, a silicon PV wafer 2300, corresponding to the P-type layer 106 of FIG. 1, prior to the doping and texturing processes has a generally flat upper surface 2302. FIG. 3B shows the wafer 2300 after N⁺ doping to form an N⁺-type layer 2304 corresponding to the N⁺ layer 200 in FIG. 1. In FIG. 3C, the N⁺-type layer 2304 has been textured to form a light-absorbing upper surface 2306 using either a wet or dry etch process as is familiar to those skilled in the art. The original front surface 2302 of the wafer 2300 in FIG. 3A is shown as a dashed line 2303 in FIG. 3C. The described front-side texturing process increases conductivity in the textured layer 2304 since the N⁺-type layer 2304 is thicker than for the conventional process shown in FIGS. 2A-2C. A further advantage is that this structure is largely immune to shunting of the device if the sharp peaks in the upper surface 2306 are broken during manufacturing since the N⁺-type layer 2304 is not a thin film conforming to the jagged topography of the upper surface 2306. However, a possible disadvantage of the process of FIGS. 3A-3C is the risk of higher electron-hole recombination due to the increased volume of N⁺ silicon in the N⁺-type layer 2304.

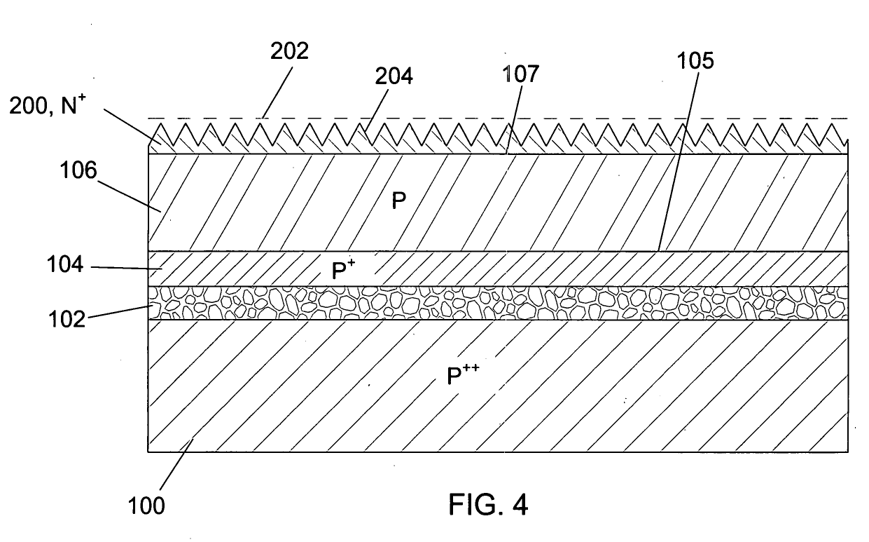

The schematic side cross-sectional view of FIG. 4 shows the wafer from FIG. 1 after texturing 204 of the front surface of the N⁺-type epitaxial layer 200 using the process illustrated in FIGS. 3A-3C. The original surface of the N⁺-type epitaxial layer 200 of FIG. 1 is shown by a dashed line 202. Since texturing is a low temperature process, the dopant distributions within the P⁺-type layer 104, the P-type layer 106, and the N⁺-type layer 200 are unchanged from those of FIG. 1.

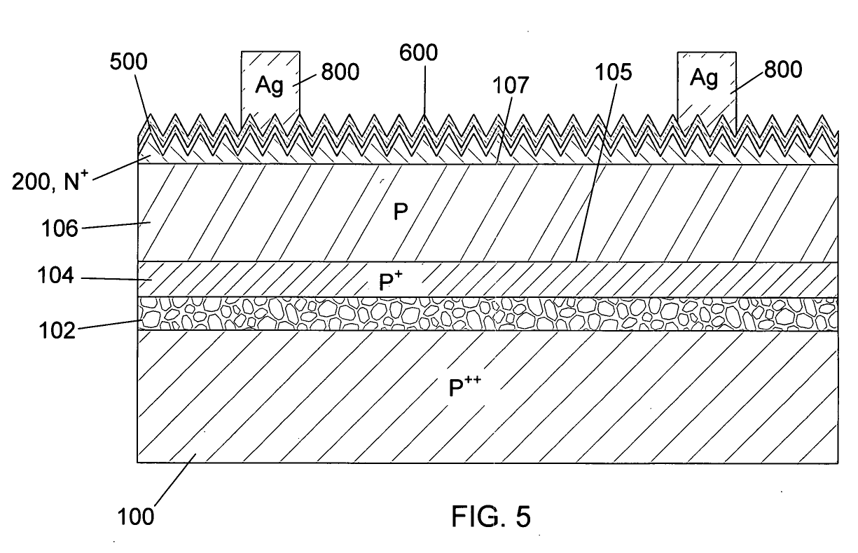

The schematic side cross-sectional view of FIG. 5 shows the wafer of FIG. 4 after three more process steps: 1) deposition of a passivation layer 500, 2) deposition of an anti-reflective coating 600, and 3) deposition of a silver contact grid 800 on the front surface of the wafer.

As is familiar to those skilled in the art, the upper surface of the textured silicon N⁺-type layer 200 may be first cleaned and then thermally oxidized (to thicknesses in the range 0.1 μm) at temperatures around 600° C. for roughly 30 minutes to form the conformal passivation layer 500. This oxidation temperature is low enough to avoid appreciable effects on the dopant distributions within the three epitaxial layers 104, 106, and 200. Alternative CVD or other deposition methods may be used to form the passivation layer 500. An oxide passivation layer 500 advantageously passivates quenches the dangling bonds at the front surface of the N⁺-type layer 200 which would otherwise induce electron-hole recombination, thereby reducing the efficiency of the PV cell. A variation of this process is the formation of the thin passivation layer by a rapid thermal oxidation (RTO) process. Alternative passivation materials include silicon carbide and amorphous silicon.

After deposition of the passivation layer 500, the anti-reflective coating (ARC) 600 may be deposited on top of the passivation layer 500. As is familiar to those skilled in the art, an anti-reflective coating reduces the amount of light reflected off the front surface of the completed PV cell, thereby increasing PV cell efficiency. The ideal anti-reflective coating will have an index of refraction which is near 4N, where N equals the index of refraction of the N⁺ layer 200. The ARC layer 600 may be deposited using physical vapor deposition (sputtering) or plasma-enhanced chemical vapor deposition as is familiar to those skilled in the art.

Following the deposition of the anti-reflective coating 600, a silver contact grid 800 may be formed on the front surface of the wafer. Since the dimensions of the contact grid 800 are relatively large (typically >0.1 mm), screen printing may be used for the initial deposition of the patterned silver contact-grid 800 on the front surface of the anti-reflective coating 600. As shown in FIG. 5, the silver material 800 initially flows down over the ARC layer 600, conforming to the topography of the ARC layer 600. Screen printing is a room-temperature process which has no effect on any of the other layers of the PV cell being manufactured.

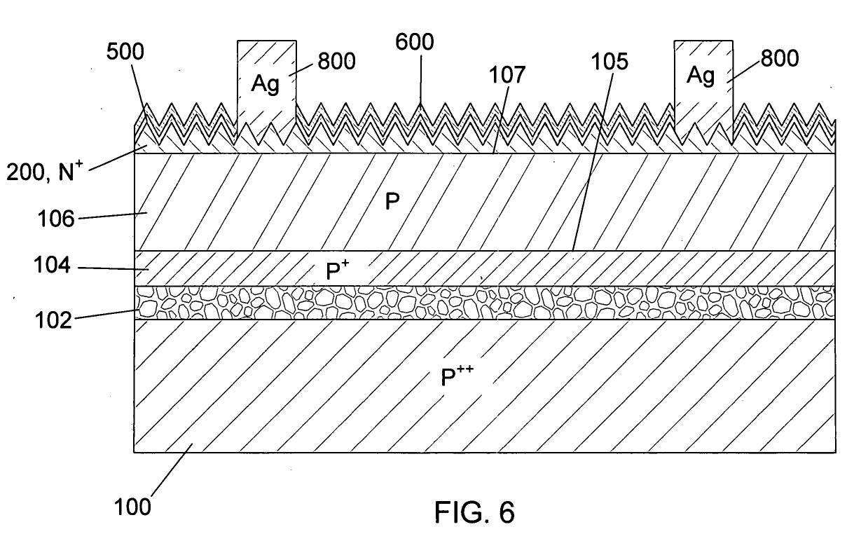

The schematic side cross-sectional view of FIG. 6 shows the wafer from FIG. 5 after firing (typically at 600° C.) of the silver contact grid 800 to make ohmic contact to the N⁺-type layer 200. Ohmic contact between the silver contact grid 800 and the N⁺-type layer 200 requires that the grid material 800 penetrates through both the ARC layer 600 and the passivation layer 500 during firing, as shown in FIG. 6.

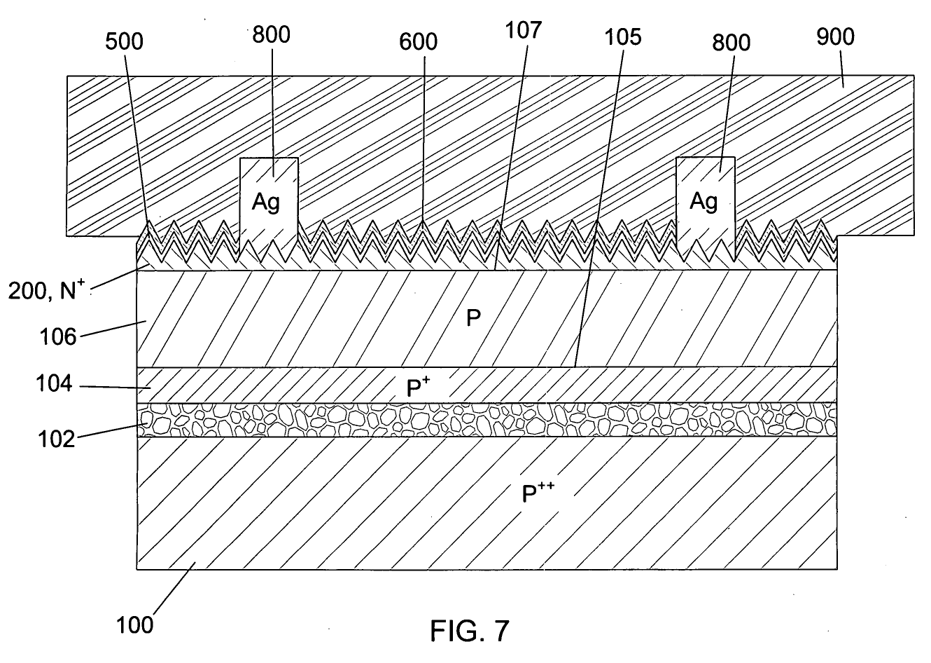

The schematic side cross-sectional view of FIG. 7 shows the wafer of FIG. 6 after clamping of the front surface of the wafer to a wafer chuck 900 over the silver contact grid 800. The wafer clamping process may involve electrostatic clamping, vacuum clamping, purely mechanical clamping, or a combination of these methods. Wafer clamping methods are familiar to those skilled in the art will not be further described. The vertical dimensions of the silver grid 800 are greatly exaggerated in the illustration of FIG. 7. Full surface contact between the lower surface of the wafer chuck 900 and the front surface of the ARC layer 600 is not necessary for adequate clamping. The small height of the silver contact grid 800 may result in some areas of the ARC layer 600 which are near to the contact grid 800 to not be in direct contact with wafer chuck 900. This lack of full contact has little effect on the operation of the wafer chuck 900 in clamping the wafer securely for subsequent processing while the structure is so clamped.

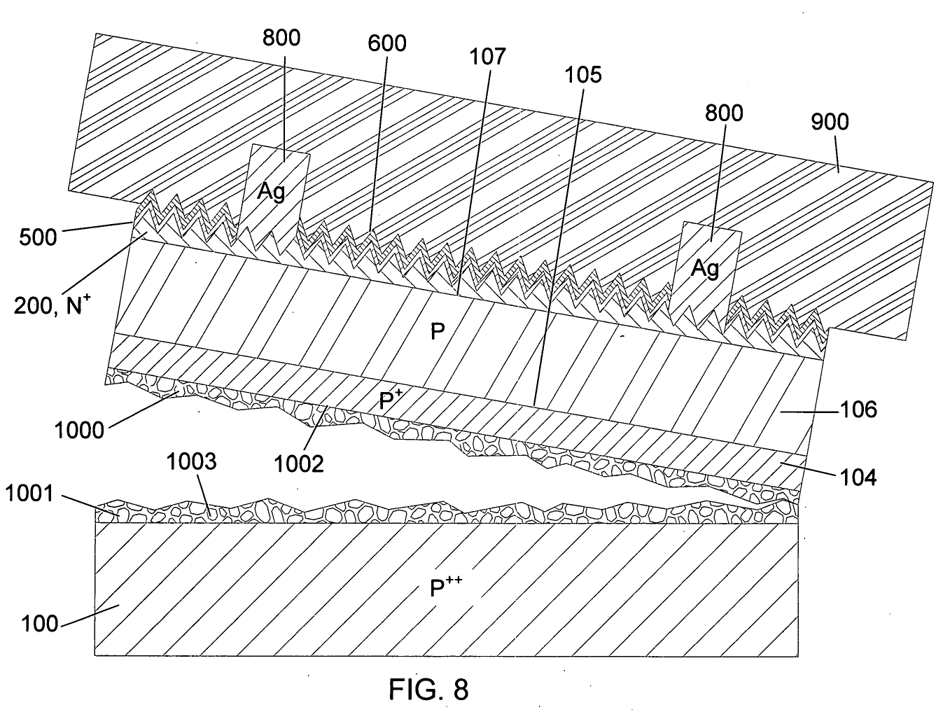

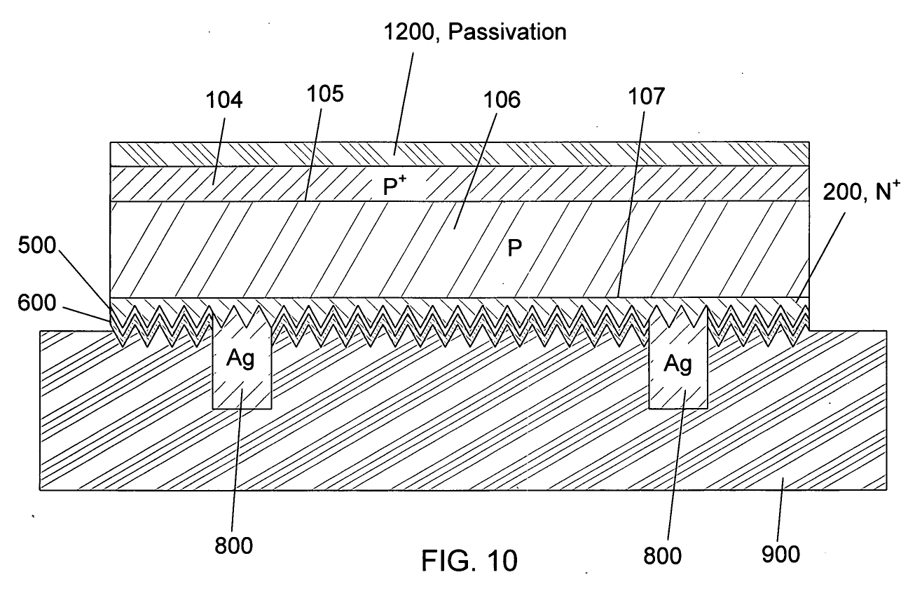

The schematic side cross-sectional view of FIG. 8 shows showing the wafer of FIG. 7 during the exfoliation process, as described in the aforecited Ser. No. 61/068,629. The bottom side of the wafer 100 is held down by other clamping means, for example, using electrostatic, vacuum or mechanical clamping. Since the wafer 100 will be relatively thick (typically greater than 200 μm), the wafer 100 will be too stiff to undergo appreciable bending during the exfoliation process. The wafer chuck 900 must have some degree of flexibility, either by means of flexible material used to fabricate the chuck 900, or by segmentation of stiff elements comprising the chuck 900. Thus, the wafer chuck 900 will support a means of exfoliating the fabricated PV cell being manufactured. An upward force, preferably including torquing, is applied to the wafer chuck 900, causing the porous layer 102 to progressively fracture from the left to the right of FIG. 10, leaving a lower partial porous layer 1001 attached at an interface 1003 to the wafer 100, and an upper partial porous layer 1000 attached at an interface 1002 to the bottom of the P⁺-type layer 104. Local torque may be provided by an intermediate stressed layer.

The schematic side cross-sectional view of FIG. 9 shows after the exfoliation process the portions of the wafer from FIG. 8 above the fracture in the porous layer 102. The upper partial porous layer 1000 remains attached at the interface 1002 to the bottom of the P⁺-type layer 104. Note that the PV cell being manufactured and the wafer chuck 900 of FIG. 9 have been turned upside down relative to their orientation in FIG. 8. This reorientation reflects the fact that all subsequent processing steps in FIGS. 10-12 will be performed on the back side of the PV solar cell being manufactured.

Several alternative exfoliation processes are illustrated in FIGS. 24-34 of the aforecited Ser. No. 61/068,629. In all of these processes, the relative mechanical weakness of the porous layer 102 relative to the wafer 100 and the P⁺-type layer 104 is exploited to separate the stack of epitaxially-grown layers 104, 106 and 200 from the mother P⁺⁺-type wafer substrate 100. Subsequent processing is then performed only on the resulting thin stack of epitaxial layers 104, 106, and 200, instead of on the entire wafer as is the case in prior art PV cell fabrication methods. This results in a substantial reduction in materials costs for the completed PV cell relative to a conventional PV cell employing wafers in the range of 200 μm in thickness since the total thickness of the epitaxially-grown layers 104, 106 and 200 is in the range of 30-50 μm in thickness. Exfoliation is a room-temperature process and this has little effect on the dopant levels and distributions within layers 104, 106 and 200. Note that since the wafer is clamped at the front side, the partial porous layer 1000 is exposed for subsequent removal.

The schematic side cross-sectional view of FIG. 10 shows the PV cell after two more process steps: 1) removal of the partial porous layer 1000 and 2) deposition or growth of a passivation layer 1200.

In the first process step, the upper partial porous layer 1000 at the interface 1002 with the P⁺-type layer 104 is removed, for example, by etching in a solution of HF/H₂O₂. Due to the porosity of the partial porous layer 1000, the etch rate of the partial porous layer 1000 is substantially higher than the etch rate of the P⁺-type layer 104, which is dense because it had been epitaxially grown as P⁺ boron-autodoped crystalline silicon. Silicon etch rates are highly density-dependent so the porous silicon is etched much faster than the crystalline epitaxially-grown silicon.

A similar etching step is applied to the mother wafer 100 to remove the lower partial porous layer 1001. Thereafter, the mother wafer 100 can again be used to grow another PV wafer. The mother wafer 100 is consumed during each sequence only to the extent needed to grow the porous layer, thereby significantly reducing the consumption of silicon.

In the second process step illustrated in FIG. 10, a passivation layer 1200 is formed on top of the P⁺-type layer 104. Note that this will be the back side of the completed PV cell, since in FIG. 10 the wafer is clamped at the front side of the PV cell being manufactured (at the bottom of FIG. 10). Because the front side of the PV cell is already metalized, a conventional furnace oxidation process is difficult in this case. One possible method for growing the passivation layer 1200 is a rapid thermal oxidation (RTO) process which converts a portion of the P⁺-type layer 104 into silicon oxide. An RTO process would enable the lower side of the wafer (with the silver contacts 800) to remain below 400° C. Another option for the passivation layer is deposition of intrinsic amorphous-silicon (α-Si) using either plasma-enhanced CVD (PECVD) or hot-wire CVD (HWCVD) processes capable of depositing roughly 10 nm of α-Si at temperatures below 400° C. HWCVD is hot wire chemical vapor deposition in which tungsten wires are electrically heated to above 2500C and process gases pass across the wires before impinging on the substrate. The hot wires crack or disassociated the chemical species to cause chemical vapor deposition on the substrate. For the passivation process, it is clearly necessary to ensure that the chuck 900 is capable of withstanding the necessary processing conditions.

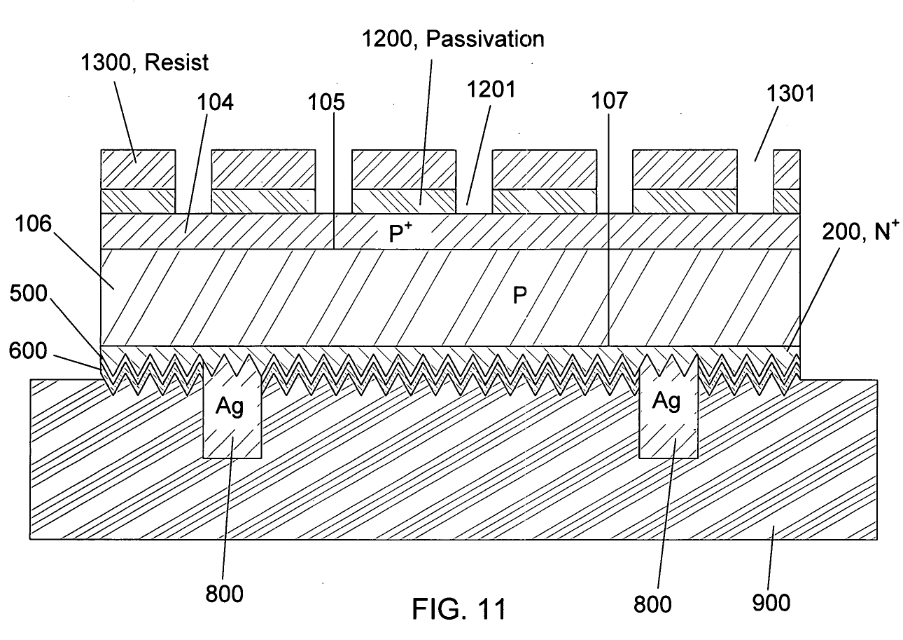

The schematic side cross-sectional view of FIG. 11 illustrates the PV cell after two more process steps: 1) deposition of a patterned film of resist 1300, an 2) an etch step, which may be isotropic, through the passivation layer 1200.

The first process step deposits a patterned layer of resist 1300 on top of the passivation layer 1200, for example, by screen printing. Resists are readily available which are resistant to the etchant being used. The openings 1301 in the resist layer 1300 will define contact areas to the P⁺-layer 104 in the second processing step shown in FIG. 11. The second process step includes isotropic etching of openings 1201 in the passivation layer 1200 using the patterned resist layer 1300 as a mask for etching. The openings 1201 in passivation layer 1200 are generally slightly larger than the openings 1301 in the resist layer 1300 due to the isotropic etching process. The P⁺-type layer 104 is exposed at the bottoms of the openings 1201 in the passivation layer 1200.

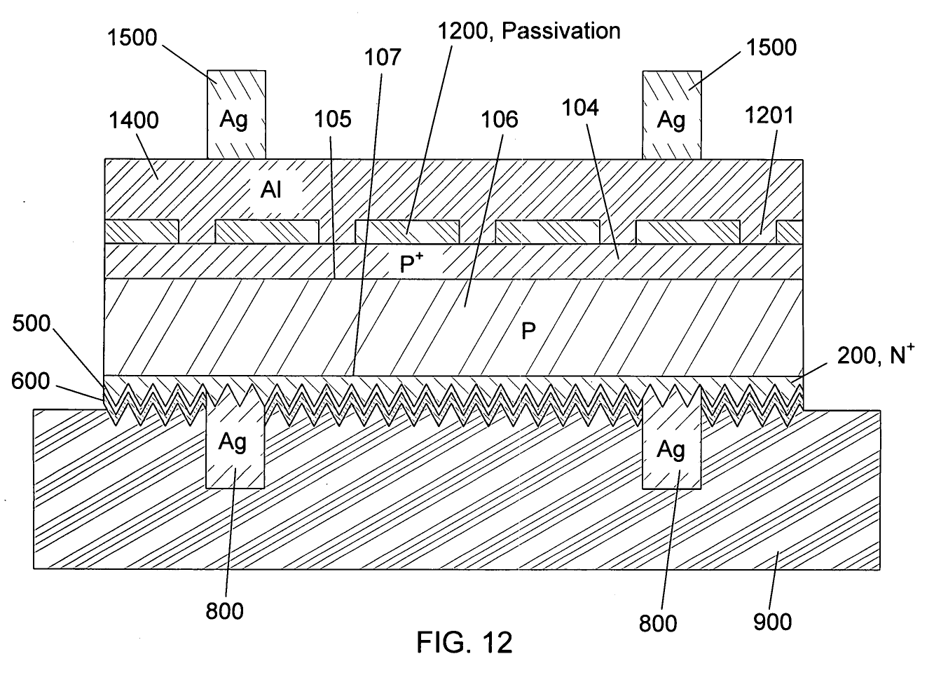

The schematic side cross-sectional view of FIG. 12 shows the PV cell after three more process steps: 1) removal of the patterned resist layer 1300, 2) deposition of an aluminum layer 1400 and subsequent annealing to form ohmic contact to the P⁺-type epitaxial layer 104, and 3) deposition of bus bars 1500, for example of silver, and annealing to make ohmic contact to the aluminum layer 1400.

The first process step removes the patterned resist layer. Generally, screen printed resists may be removed using appropriate solvents as is familiar to those skilled in the art. The second process step deposits an aluminum layer 1400 and subsequent anneals at least the upper portions of the wafer to form ohmic contacts from the aluminum layer 1400 to the P⁺-type epitaxial layer 104 at the bottoms of the openings 1201 in the passivation layer 1200. Typically, the aluminum layer 1400 will be about 2 microns thick and can be deposited using standard PVD (sputtering) methods familiar to those skilled in the art. After sputter deposition, the aluminum layer 1400 must be annealed at about 400° C. to make ohmic contact to the P⁺-type layer 104. Again, the wafer chuck 900 must be able to withstand the necessary processing conditions. The aluminum layer 1400 serves the dual purposes of providing contact to the P⁺-type layer 104, while also reflecting light passing through the PV wafer back through the epitaxially-grown layers 104, 106 and 200, thereby increasing the PV cell efficiency.

The third process step of FIG. 12 deposits silver bus bars 1500 and subsequently anneals the deposited silver paste. The silver bus bars 1500 may be patterned using conventional screen printing techniques. After deposition, the bus bars 1500 may be annealed to drive off the binder paste in the printed silver paste and to densify the paste to produce the needed conductivity.

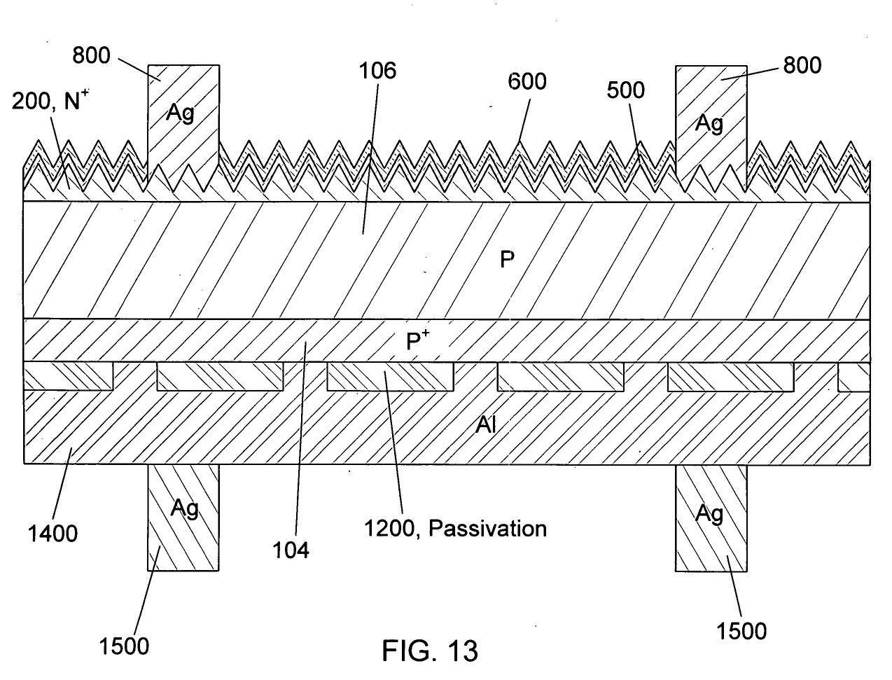

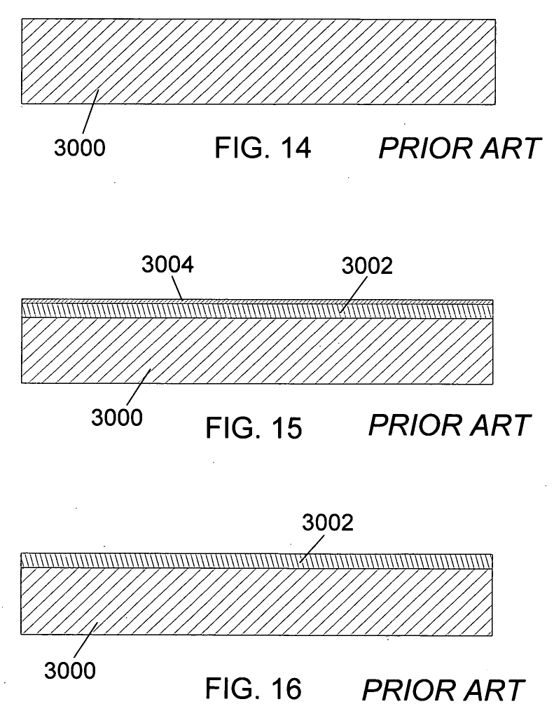

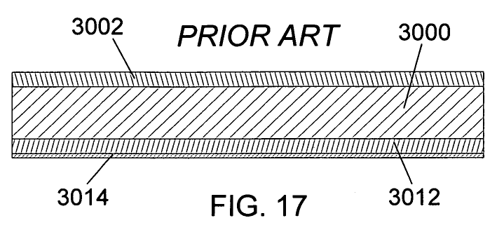

A completed thin photovoltaic solar cell of the present invention is shown in the cross-sectional view of FIG. 13 after being removed from the wafer clamp 900. Note that in FIG. 13, the PV cell has been turned right side up, to place the light collecting side on the top.

Several of the thus fabricated solar cells are typically interconnected in series between the top of one cell and the bottom of the adjacent cell to form a string to build up the voltage to a convenient operational level. A multitude of these strings are then placed by appropriate robotics on a layer of, for example, ethylene vinyl acetate (EVA) on top of a backing material, typical a polymer available from DuPont called Tedlar supported on a lay up table. The strings are attached together through connecting straps of solder-coated copper to produce parallel connected strings. Another layer of EVA is placed on the string array followed by a glass sheet. The entire assembly is put into an autoclave or lamination chamber to laminate the assembly to complete the manufacture of the solar module.

It will be understood by those skilled in the art that the foregoing descriptions are for illustrative purposes only. A number of modifications to the above fabrication sequence and PV cell design are possible within the scope of the present invention, such as the following.

Alternative methods of etching through the passivation layer 1200 are possible instead of wet etching, including Reactive Ion Etching (RIE), or laser ablation. In the RIE process, the plasma contains chemical species (both ions and radicals) which react with passivation layer 1200. Both wet and dry (plasma) etch methods for oxide are well known to those skilled in the art and are not part of the present invention.

An alternative method for removing resist instead of a wet solution is possible. Plasma ashing processes may also be used to selectively remove resist—both wet and dry (plasma) processes for resist removal are well known to those skilled in the art and are not part of the present invention.

An alternative to the use of screen printing of patterned resist layers is possible. A continuous film of resist may be deposited and subsequently patterned using photolithography. Both of these resist patterning methods are familiar to those skilled in the art and are not part of the present invention.

Other metals than aluminum and silver may be used. The semiconductor dopants are not limited to those mentioned. The P-type and N-type doping may be interchanged.

The improved PV cell of the present invention enables the following desirable features.

The consumption of silicon is reduced compared with the conventional thick wafer process.

The epitaxial deposition of the active silicon layers on porous silicon for the formation of very thin silicon wafers avoids multiple energy-intensive steps characteristic of the conventional process, such as (a) converting trichlorosilane to solid silicon in a Siemens reactor, (b) melting and growth of single crystals from the resulting high purity silicon, (c) machining of the round ingot from the crystal growth process into quasi-square blocks, and (d) subsequent slicing of the blocks into thin wafers and the removal of slicing induced damage by chemical etching.

The P⁺-P and N⁺-P junctions can be formed in situ during epitaxial deposition processes and dopant profiles within the PV cell are better controlled The PV wafer is partially processed while the thin, epitaxially deposited layer is still attached to the underlying porous silicon layer and the thick silicon substrate through all the processing steps on one side of the wafer, which will be the front surface of the completed PV cell, thus avoiding this process on fragile, thin structures. These steps include oxidation, junction formation, texturing, deposition of an anti-reflective coating, deposition of one set bus grids, and contact formation.

The partially completed solar cell is attached to a wafer chuck for exfoliating the cell from the substrate at the porous layer and completing cell processing on the reverse side (back surface) of the cell, including etching to remove remnants of the porous layer, deposition of passivation and a second set of bus grids, and formation of contacts.

The number of processing steps is substantially reduced compared with the prior art furnace diffusion fabrication method, thereby lowering manufacturing costs.

Fabrication yields may be increased through reduced breakage during processing due to the reduced number of processing steps and new approaches for handling very thin silicon wafers through various processing operations.

What is claimed is:

1. A thin photovoltaic (PV) solar cell, comprising:
A monocrystalline first film of silicon of a first conductivity type at a low doping concentration;
a second film of silicon of the first conductivity type at a medium concentration formed on the lower surface of said second film and epitaxial therewith, wherein the first film is formed by a diffusion process producing an exponential doping profile;
a third film of silicon of a second conductivity type other than the first conductivity type at a medium concentration epitaxial with the upper surface of the second film; and
a passivating film formed on the lower surface of the third film; wherein
a multiplicity of openings are formed through the passivating film;
a conducting film is formed on the lower surface of the passivating film, wherein the conducting film fills said openings in the passivating film to make contact with the third film;
first contacts deposited on the lower surface of said conducting film; and
second contacts deposited on the upper surface of the third film.

2. The solar cell as in claim 1, wherein the PV solar cell includes the silicon layers which are epitaxial therebetween and include the first, second, and third films, and wherein the silicon layers, the passivating film and the conducting film have a total a thickness of no more than 100 microns.

3. The solar cell as in claim 1, wherein the upper surface of the third film includes a generally planar lower surface and a textured upper surface to improve the light collection efficiency of the PV solar cell, and wherein the second contacts contact the textured upper surface.

4. The solar cell as in claim 3, further comprising a passivation layer on the textured upper surface and wherein the second contacts penetrate the passivation layer and contact the third film.

5. The solar cell as in claim 4, wherein said passivation layer is a silicon oxide layer.

6. The solar cell as in claim 4, wherein said passivation layer is a layer of amorphous silicon.

7. The solar cell as in claim 4, further comprising an anti-reflective coating on the upper surface of the passivation layer deposited before the deposition of the second contacts on the upper surface of the third film.

8. The solar cell as in claim 7, wherein the anti-reflective coating comprises silicon nitride.

9. The solar cell as in claim 1, wherein the combined thickness of the first, second and third films and the passivating film is in the range 30 to 50 microns.

10. The solar cell as in claim 1, wherein the combined thickness of the first, second and third film and the passivating film is in the range 50 to 100 microns.

11. The solar cell as in claim 1, wherein the first conductivity type is P type and the second conductivity type is N type.

12. A thin photovoltaic (PV) solar cell, comprising
a monocrystalline first film of silicon of a first conductivity type at a low doping concentration;
a second film of silicon of the first conductivity type at a medium concentration formed on the lower surface of the first film and epitaxial with the first film;
a third film of silicon of a second conductivity type other than the first conductivity type at a medium concentration formed on the upper surface of the second film, epitaxial with the second film, and having a generally planar upper surface adjacent the second film and a textured lower surface; and
a conformal anti-reflection coating deposited on the textured lower surface of the second film.
a multiplicity of openings are formed through the anti-reflection coating;
a conducting film formed on the lower surface of the anti-reflection coating, wherein the conducting film fills the said openings in the anti-reflection coating film to make contact with the third film;
first contacts deposited on the lower surface of said conducting film; and
second contacts deposited on the upper surface of the third film.

13. The solar cell as in claim 12, wherein the PV solar cell includes silicon layers which are epitaxial therebetween and include the first, second, and third films, and wherein the silicon layers, the anti-reflection coating and the conducting film have a total a thickness of no more than 100 microns.

14. A thin photovoltaic solar cell, comprising:
a support; and
a generally planar photovoltaic structure bonded to the support and including semiconductor silicon layers epitaxial with each other and including a P-N junction between the silicon layer and further including front side contacts on a side receiving radiation and back side contacts on the opposed sides, wherein the silicon layers have a total thickness of no more than 100 microns.

15. The solar cell of claim 14, wherein the silicon adjacent the front side is textured on the front side thereof and planar on the backside thereof.

16. The solar cell of claim 14, wherein the silicon layers consist of three silicon layers.

17. The solar cell of claim 14, wherein the total thickness is no more than 60 microns.

18. A method for fabricating a photovoltaic solar cell on a thick wafer, comprising the steps of:
a. forming a porous layer of silicon on the upper surface of a heavily doped silicon wafer of a first conductivity type
b. epitaxially growing a moderately doped first layer of silicon of the first conductivity type on the upper surface of the porous silicon layer, wherein said epitaxial growth process induces the formation by autodoping of a moderately doped second layer of the first conductivity type in contact with the porous layer and within the first layer; and
c. epitaxially growing a moderately doped third layer of silicon of a second conductivity type other than the first conductivity type on the upper surface of the second layer.

19. The method as in claim 18, further comprising texturing the upper surface of the third layer opposite the first layer.

20. The method as in claim 19, further comprising forming a passivation layer on top of the textured upper surface of the third layer.

21. The method as in claim 20, further comprising depositing an anti-reflective layer on top of the passivation layer.

22. The method as in claim 21, further comprising depositing a multiplicity of contacts on top of the anti-reflective coating.

23. The method as in claim 22, further comprising firing said PV solar cell to sinter the multiplicity of contacts in order to form ohmic contacts with said the third layer through the passivating layer and the anti-reflective coating.

24. The method as in claim 23, further comprising clamping the upper surface of said PV solar cell with a wafer clamp.

25. The method as in claim 24, further comprising separating said porous silicon layer in an exfoliation process including movement of the wafer clamp relative to the thick wafer.

26. The method as in claim 25, wherein the exfoliation process-includes a mechanical fracturing process.

27. The method as in claim 25, further comprising removing the portion of the porous silicon layer remaining in contact with the second layer after the exfoliation process.

28. The method as in claim 27, further comprising forming of a second passivation layer on top of the second layer.

29. The method as in claim 28, wherein the second passivation layer comprises a layer of silicon oxide grown using a rapid thermal oxidation process.

30. The method as in claim 28, wherein the second passivation layer comprises a layer of amorphous silicon deposited using chemical vapor deposition.

31. The method as in claim 28, further comprising the steps of:
depositing a patterned layer of resist on top of the second passivation layer, wherein the layer of resist has a multiplicity of openings;
etching openings in the second passivation layer through openings in the said patterned layer of resist; and
thereafter removing the patterned layer of resist.

32. The method as in claim 31, further comprising depositing a conducting layer on top of the second passivation layer, wherein said conducting layer fills the openings in said second passivation layer.

33. The method as in claim 32, further comprising firing the photovoltaic solar cell to sinter said conducting layer to make ohmic contact with the second layer through the openings in the second passivation layer.

34. The method as in claim 33, further comprising depositing contacts on top of the conducting layer, wherein the contacts connect with the second layer through the conducting layer.

35. The method cell as in claim 18, wherein the porous layer is formed by electrochemical etching.

36. The method as in claim 18, further comprising smoothing the upper surface of the porous layer prior to growing the first layer.

37. The method as in claim 36, wherein the smoothing step includes rapid thermal processing.
